(19) United States
(12) Patent Application Publication
(10) Pub. No.: US 2011/0186979 A1
(43) Pub. Date: Aug. 4, 2011

(54) SEMICONDUCTOR PACKAGE AND HIGH-FREQUENCY SEMICONDUCTOR DEVICE

(75) Inventor: Tomohiro SENJU, Kanagawa-ken (JP)

(73) Assignee: Kabushiki Kaisha Toshiba, Tokyo (JP)

(21) Appl. No.: 12/974,770

(22) Filed: Dec. 21, 2010

(30) Foreign Application Priority Data
Feb. 3, 2010 (JP) 2010-021952

(51) Int. Cl. H01L 23/48

(52) U.S. Cl. 257/690; 257/E23.01

(57) ABSTRACT

According to an embodiment, a semiconductor package includes: a base substrate made of a metal; a frame body made of a dielectric, placed on a surface of the base substrate, and including an opening portion in its center portion; a seal member placed on an upper surface of the frame body, and including an opening portion in its center portion; and a lid portion placed on an upper surface of the seal member. The thickness of the seal member is substantially equal to that of the base substrate, and a coefficient of linear expansion of the seal member is substantially equal to that of the base substrate. The base substrate, the first frame body, the second frame body, the seal member and the lid portion form a space.

### CROSS-REFERENCE TO RELATED APPLICATION

This application is based upon and claims the benefit of priority from the prior Japanese Patent Application No. 2010-021952, filed on Feb. 3, 2010, the entire contents of which are incorporated herein by reference.

### FIELD

Embodiments described herein relate to a semiconductor package for hermetically-sealing a high-frequency semiconductor chip, and a high-frequency semiconductor device using the semiconductor package.

### BACKGROUND

A conventional high-frequency semiconductor device includes: a semiconductor package formed from a hermetic container made of a dielectric; and a high-frequency semiconductor chip mounted inside this package. The semiconductor package includes: a flat-shaped substrate on which a semiconductor chip is placed; a frame body placed on this substrate in a way to surround the semiconductor chip; and a lid placed on this frame body. In addition, high-frequency lines extending from the inside to the outside of the frame body while penetrating the frame body are formed in the frame body. The semiconductor chip is connected to the lines inside the frame body. An input lead terminal and an output lead terminal are connected to the lines outside the frame body (see JP, P2006-80380A and JP, P2006-121118A).

The above-described high-frequency semiconductor device is manufactured, for example, as follows. First of all, the frame body is soldered onto the substrate by use of a solder material. Subsequently, the input lead terminal and the output lead terminal are soldered onto the lines outside the frame body by use of a solder material. Thereafter, the semiconductor chip is soldered onto the substrate inside the frame body by use of a solder material, and the semiconductor chip is connected to the lines inside the frame body through wires. Finally, the lid is soldered onto the frame body with a solder material. Thereby, the semiconductor chip is mounted in the semiconductor package, and the high-frequency semiconductor device is completed.

The semiconductor chip produces heat during its operation. For this reason, the heat produced by the semiconductor chip needs to be efficiently released to the outside of the semiconductor package. To this end, it is conceivable to form a substrate from a metal material having an excellent heat release effect. However, the following problems occur in the case where the substrate is made of the metal material.

In each soldering step in the manufacturing process of the high-frequency semiconductor device, the entire semiconductor package or the entire high-frequency semiconductor device is heated to melt the solder material. Nevertheless, the coefficient of linear expansion of the substrate and the coefficient of linear expansion of the frame body are different from each other. For this reason, the flatness of the upper surface of the frame body is deteriorated due to the heat cycles in the manufacturing process. If the lid is placed on the frame body which has lost its flatness, a gap occurs between the frame body and the lid, and the hermetic quality of the semiconductor package accordingly degenerates.

Furthermore, the reliability of the high-frequency semiconductor device decreases because moisture, dust and the like enter the inside of the semiconductor package through the gap between the frame body and the lid portion.

### BRIEF DESCRIPTION OF THE DRAWINGS

FIG. 1 is a perspective view schematically showing a semiconductor package according to an embodiment;

FIG. 2 is a cross-sectional view of a high-frequency semiconductor device taken along line I-I of FIG. 1;

FIG. 3 is a plan view of a first frame body;

FIG. 4 is a cross-sectional view of the high-frequency semiconductor device taken along line II-II of FIG. 2; and

FIG. 5 is a cross-sectional view of the high-frequency semiconductor device taken along line III-III of FIG. 2.

### DETAILED DESCRIPTION

A semiconductor package according to an embodiment includes: a base substrate made of a metal; a first frame body made of a dielectric, placed on a surface of the base substrate, and including a first opening portion in its center portion; a plurality of lines formed on an upper surface of the first frame body, the lines each traversing the first frame body; a second frame body made of a dielectric, placed on the upper surface of the first frame body in a way that two end portions of each of the lines are exposed, and including a second opening portion in its center portion; a seal member placed on an upper surface of the second frame body, and including a third opening portion in its center portion; and a lid portion placed on an upper surface of the seal member. The thickness of the seal member is substantially equal to that of the base substrate, and a coefficient of linear expansion of the seal member is substantially equal to that of the base substrate. The base substrate, the first frame body, the second frame body, the seal member and the lid portion form a space. One of the two end portions of each of the lines is exposed to the space.

A high-frequency semiconductor device comprising according to an embodiment includes: the semiconductor package mentioned above; a semiconductor chip situated in the space of the semiconductor package, and placed on the surface of the base substrate; and conductors electrically connecting the semiconductor chip and the end portions of the lines exposed to the space.

In the semiconductor package according to the embodiment, the seal member made of a metal whose thickness is substantially equal to that of the base substrate, and whose coefficient of linear expansion is substantially equal to that of the base substrate, is placed on the frame body made of a dielectric. For this reason, the distortions of the frame body which occur when a heat cycle is applied are offset. Accordingly, even though the heat cycle is applied, the distortion of the seal member placed on the upper surface of the frame body is inhibited, and the flatness of the upper surface of the seal member is thus maintained. Thereby, the hermetic quality of the semiconductor package is enhanced.

The embodiment provides a semiconductor package capable of inhibiting moisture, dust and the like from entering its inside. Accordingly, the embodiment provides a high-frequency semiconductor device having excellent reliability.

Hereinafter, referring to the drawings, detailed descriptions will be provided for the semiconductor package and the high-frequency semiconductor device using the same according to the embodiment.

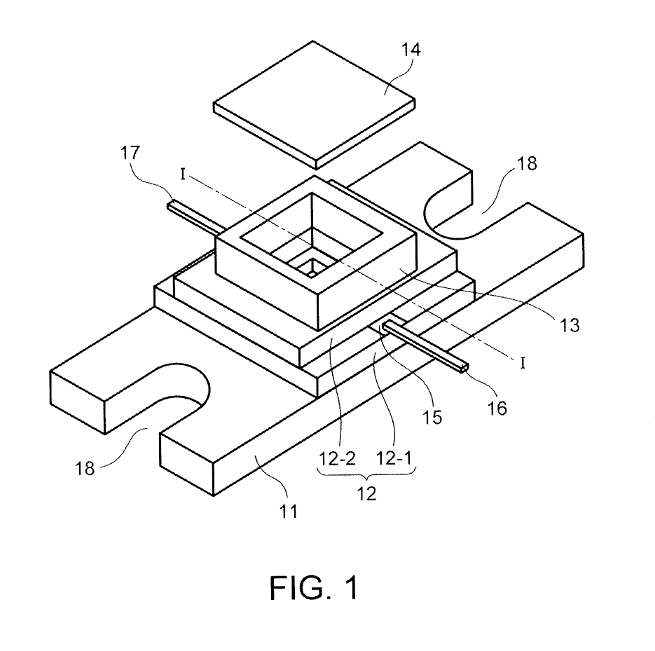

FIG. 1 is a perspective view schematically showing the semiconductor package according to the embodiment. In FIG. 1, some parts of the semiconductor package are omitted and other parts of the semiconductor package are exploded. The semiconductor package includes: a base substrate 11; a frame body 12 placed on the base substrate 11; a seal member 13 placed on the frame body 12; and a lid portion 14 placed on the seal member 13.

Lines 15 penetrating the frame body 12 between the inside and the outside are provided in the frame body 12. An input lead terminal 16 and an output lead terminal 17 are respectively provided on the lines 15 in opposed positions in the outside of the frame body 12.

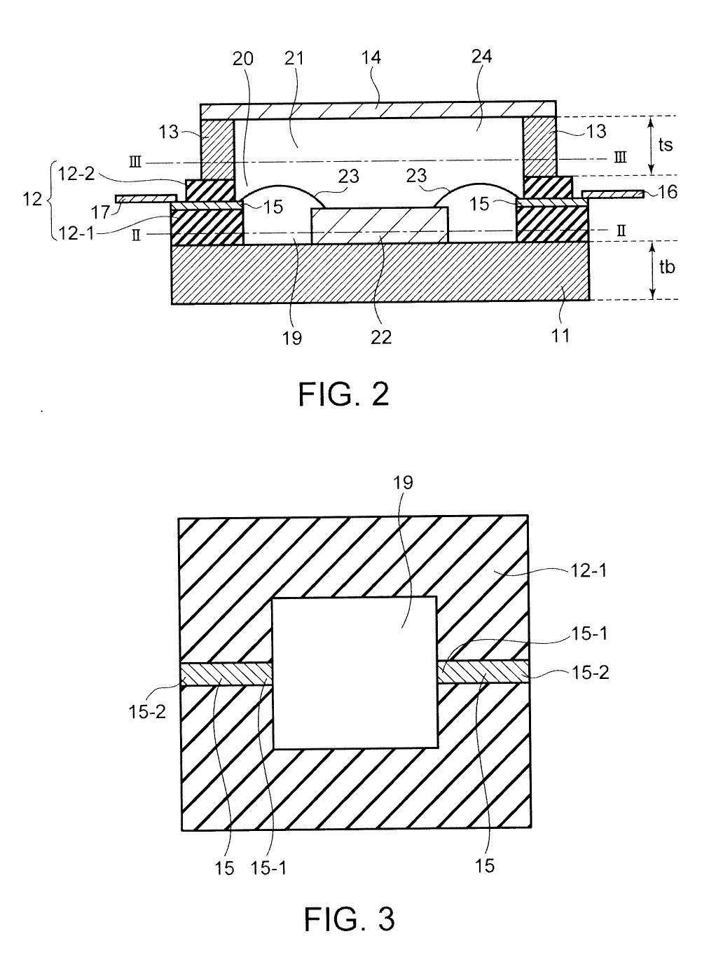

FIG. 2 is a cross-sectional view of the semiconductor package taken along line I-I of FIG. 1. FIG. 2 shows the semiconductor package and a semiconductor chip 22 provided in the inside of the semiconductor package. In other words, FIG. 2 shows a high-frequency semiconductor device.

First of all, descriptions will be provided for a configuration of the semiconductor package. The base substrate 11 is shaped like a plate. The thickness tb of the base substrate 11 is approximately 1 mm, for example. The planar shape of the base substrate 11 is rectangular. The base substrate 11 is made of an alloy of copper and molybdenum, for example. For this reason, the semiconductor package according to this embodiment is better in heat release effect than a conventional semiconductor package which includes a base substrate made of a dielectric such as a ceramic.

It should be note that, as shown in FIG. 1, the base substrate 11 has recessed portions 18 in its opposed side portions, respectively. These recessed portions 18 form parts of the respective screw holes which are used to mount the high-frequency semiconductor device on a mount substrate (not illustrated) or the like.

The frame body 12 is placed on the base substrate 11 with a solder material (not illustrated) interposed in between, for example. The frame body 12 is soldered to the base substrate 11. The frame body 12 includes a first frame body 12-1, and a second frame body 12-2 placed on this first frame body 12-1.

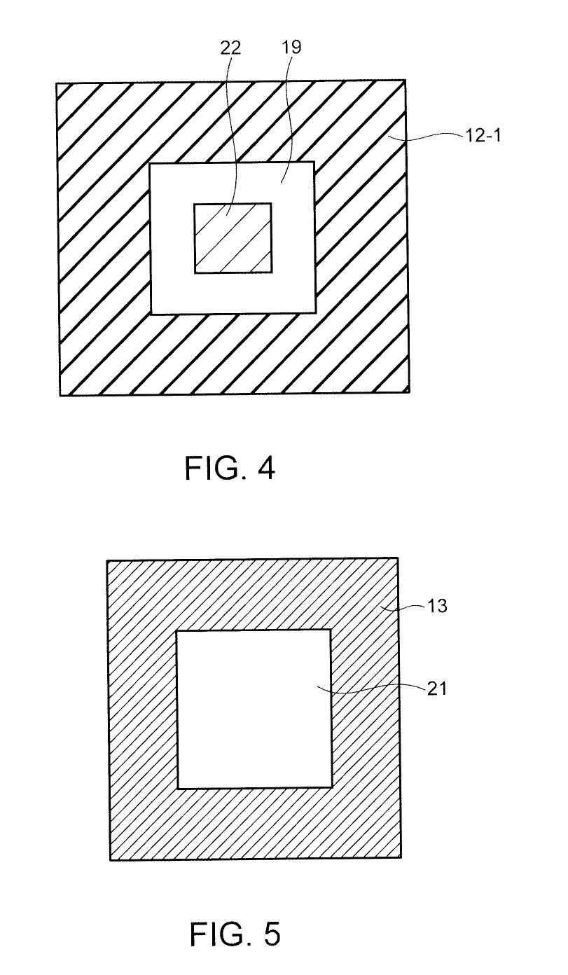

FIG. 3 is a plan view of the first frame body 12-1. FIG. 4 is a cross-sectional view of the first frame body 12-1 taken along line II-II of FIG. 2. The first frame body 12-1 has a certain thickness, and is shaped like a frame. In other words, the first frame body 12-1 has the certain thickness; the shape of cross section (hereinafter referred to as a cross-sectional shape) along the base substrate 11 is a square; and it has a first opening portion 19, which is shaped like a square, in its center portion. The first frame body 12-1 is made of a dielectric such as a ceramic.

Two lines 15 are provided on the upper surface of the first frame body 12-1. The two lines 15 are formed in a way that: the first opening portion 19 is located between the two lines 15; and each line 15 traverses the first frame body 12-1. For example, each line 15 is a microstrip line, and is made of a conductor such as nickel. The surface of the conductor is covered with gold. An end portion of each line 15 near the first opening portion 19 will be referred to as a first end portion 15-1, and the other end portion of the line 15 near the peripheral portion of the first frame body 12-1 will be referred to as a second end portion 15-2.

Referring to FIG. 2 again, the input lead terminal 16 and the output lead terminal 17 are provided on the second end portions 15-2 of the lines 15 provided to the first frame body 12-1, respectively. These lead terminals 16, 17 are the input and output terminals of the high-frequency semiconductor device, and are fixed onto the second end portions 15-2 of the lines 15 by soldering using a solder material, for example. The lead terminals are not limited to the input lead terminal 16 and the output lead terminal 17, and the number of lead terminals is not limited to two. The semiconductor package can have many lead terminals if needed. The semiconductor package can have a lead terminal of uses other than an input and an output if needed.

The second frame body 12-2 is placed on the upper surface of the first frame body 12-1 with an insulating material (not illustrated), such as an epoxy resin, interposed in between. The second frame body 12-2 is bonded to the first frame body 12-1. The shape of the second frame body 12-2 is similar to that of the first frame body 12-1. However, the size of the second frame body 12-2 is different from that of the first frame body 12-1. To put it specifically, the frame width of the second frame body 12-2 is narrower than that of the first frame body 12-1. In addition, the second frame body 12-2 has a certain thickness. Furthermore, the cross-sectional shape of the second frame body 12-2 is a square whose sides are shorter than those of the square of the frame body 12-1. The second frame body 12-2 has a second opening portion 20, which is shaped like a square, in its center portion. The length of the sides of the second opening portion 20 is longer than the length of the sides of the first opening portion 19. This second frame body 12-2 is made of a dielectric such as a ceramic as well.

The second frame body 12-2 is placed on the upper surface of the first frame body 12-1 in a way that the two end portions of each line 15, namely, the first end portion 15-1 and the second end portion 15-2 of each line 15, are exposed from the second frame body 12-2.

The seal member 13 is placed on the upper surface of the second frame body 12-2 with a solder material (not illustrated), for example, interposed in between. The seal member 13 is fixed to the second frame body 12-2 by soldering. FIG. 5 is a cross-sectional view of the seal member 13 taken along line III-III of FIG. 2. The shape of the seal member 13 is similar to those of the first and second frame bodies 12-1, 12-2. However, the size of the seal member 13 is different from those of the first and second frame bodies 12-1, 12-2. To put it specifically, the frame width of the seal member 13 is narrower than that of the second frame body 12-2. In addition, as shown in FIG. 2, the thickness is of the seal member 13 is substantially equal to the thickness tb of the base substrate 11. Furthermore, as shown in FIG. 5, the cross-sectional shape of the seal member 13 is a square whose sides are shorter than those of the square of the second frame body 12-2. The seal member 13 has a third opening portion 21, which is shaped like a square, in its center portion. The length of the sides of the third opening portion 21 is equal to the length of the sides of the second opening portion 20. This seal member 13 is made of an alloy of iron, nickel and cobalt, for example. The coefficient of linear expansion of this alloy is substantially equal to that of the alloy of which the base substrate 11 is made.

It is desirable that the coefficient of linear expansion of the seal member 13 and the coefficient of linear expansion of the base substrate 11 should be substantially equal to each other; and the base substrate 11 and the seal member 13 may be made of different materials as described above, or may be made of the same material.

As shown in FIG. 2, the seal member 13 is placed on the second frame body 12-2 in a way that the third opening portion 21 coincides with the second opening portion 20 of the second frame body 12-2.

The plate-shaped lid 14 made of a metal, for example, is placed on the upper surface of the seal member 13 with a solder material (not illustrated), for example, interposed in between. The lid 14 is soldered to the seal member 13. Incidentally, the lid 14 may be made of an insulating material such as a ceramic and a resin, instead of the metal.

The base substrate 11, the first frame body 12-1, the second frame body 12-2, the seal member 13 and the lid 14 form a space 24 for containing the high-frequency semiconductor chip 22 (not illustrated in FIG. 1). In addition, the first end portions 15-1 of the respective lines 15 are exposed to the space 24.

Next, descriptions will be provided for the high-frequency semiconductor device according to the embodiment. The high-frequency semiconductor device includes: the semiconductor package described above; and the semiconductor chip 22 hermetically contained in the inside of this semiconductor package.

Referring to FIG. 2, the semiconductor chip 22 is placed on the upper surface of the base substrate 11 which constitutes part of the semiconductor package. The semiconductor chip 22 is a field-effect transistor, for example. The base substrate 11, the first frame body 12-1, the second frame body 12-2, the seal member 13 and the lid 14 form the hermetic space 24. This semiconductor chip 22 is situated in the hermetic space 24, and is placed on the upper surface of the base substrate 11 with the solder material (not illustrated), for example, interposed in between. The semiconductor chip 22 is soldered to the base substrate 11.

The semiconductor chip 22 is electrically connected to the first end portions 15-1 of the lines 15 provided on the upper surface of the first frame body 12-1 through conductors such as wires 23, for example. Thereby, a high-frequency signal to be inputted into the high-frequency semiconductor device is inputted into the semiconductor chip 22 through the input lead terminal 16, the corresponding strip line 15 and the corresponding wire 23, and is then subjected to a desired signal process in the semiconductor chip 22. The processed high-frequency signal is outputted from the high-frequency semiconductor device through the other wire 23, the other strip line 15 and the output lead terminal 17.

Next, descriptions will be provided for a method of manufacturing the semiconductor package and the high-frequency semiconductor device. First of all, the first frame body 12-1 is soldered onto the base substrate 11 by use of the solder material. Subsequently, the input lead terminal 16 and the output lead terminal 17 are soldered onto the second end portions 15-2 of the lines 15 provided on the first frame body 12-1 by use of the solder material, respectively. Afterward, the second frame body 12-2 is bonded onto the first frame body 12-1 by use of the insulating material such as an epoxy resin, for example. Thereafter, the semiconductor chip 22 is soldered onto the base substrate 11 in the inside of the frame body 12 by use of the solder material. In addition, the first end portions 15-1 of the lines 15 which are exposed to the inside of the frame body 12 are connected to the semiconductor chip 22 through the respective wires 23. Finally, the lid 14 is soldered onto the frame body 12 by use of the solder material. Thus, the semiconductor package according to the embodiment is obtained, and the high-frequency semiconductor device according to the embodiment which includes the semiconductor chip 22 hermetically sealed in the semiconductor package is obtained.

In the semiconductor package according to the embodiment, the seal member 13 is bonded to the second frame body 12-2 made of the dielectric. The seal member 13 is made of the metal whose thickness is substantially equal to that of the base substrate 11, and whose coefficient of linear expansion is substantially equal to that of the base substrate 11. For this reason, when a heat cycle is applied, the stress caused in the second frame body 12-2 by the contraction of the base substrate 11 after its thermal expansion is offset by the stress caused in the second frame body 12-2 by the contraction of the seal member 13 after its thermal expansion. To put it specifically, because the coefficient of linear expansion of the base substrate 11 is larger than the coefficient of linear expansion of the second frame body 12-2, the base substrate 11 once having thermally expanded during the soldering contracts after the soldering. Consequently, the stress which deforms the second frame body 12-2 in a way to curve upward is applied to the second frame body 12-2. On the other hand, because the coefficient of linear expansion of the seal member 13 is substantially equal to the coefficient of linear expansion of the base substrate 11, the seal member 13 thermally expands as much as the base substrate 11 during the soldering. Consequently, the stress which deforms the second frame body 12-2 in a way to curve downward is applied to the second frame body 12-2 after the soldering. For this reason, the stresses applied to the second frame body 12-2 are offset by each other. Thereby, the loss of the flatness of the upper surface of the second frame body 12-2 is inhibited even though the heat cycle is applied. Thus, the distortion of the seal member 13 placed on the upper surface of the second frame body 12-2 is inhibited as well. Accordingly, the lid 14 can be placed there with generating no gap between the seal member 13 and the lid portion 14. In other words, the hermetic quality of the semiconductor package is enhanced.

As a result, the semiconductor package according to the embodiment is capable of preventing moisture, dust and the like from entering the inside of the semiconductor package. In addition, the semiconductor package according to the embodiment is capable of sealing the semiconductor chip 22 in the inside of the semiconductor package in an excellent hermetic condition. For this reason, the semiconductor package makes it possible to offer the high-frequency semiconductor device with excellent reliability.

The foregoing descriptions have been provided for the semiconductor package and the high-frequency semiconductor device according to the embodiment. However, the present invention is not limited to the above-described embodiment. The present invention can be applied to: any semiconductor package whose base substrate is made of a metal, and whose frame body is made of a dielectric; and any high-frequency semiconductor device using such a package.

For this reason, the cross-sectional shape of the frame body 12 and the seal member 13, for example, does not have to be square as described above. The cross-sectional shape may be any other shape such as a rectangle, an octagon, a circle and an ellipse. The cross-section shape is not limited to anything particular. Furthermore, the shape of the first to third opening portions 19, 20, 21 formed in the frame body 12 and the seal member 13 is not limited, and may be any other shape.

While certain embodiment has been described, this embodiment have been presented by way of example only, and are not intended to limit the scope of the inventions. Indeed, the novel embodiment described herein may be embodied in a variety of other forms; furthermore, various omissions, substitutions and changes in the form of the embodiment described herein may be made without departing from the spirit of the inventions. The accompanying claims and their equivalents are intended to cover such forms or modifications as would fall within the scope and spirit of the inventions.

What is claimed is:

1. A semiconductor package comprising:
a base substrate made of a metal;
a first frame body made of a dielectric, placed on a surface of the base substrate, and including a first opening portion in its center portion;
a plurality of lines formed on an upper surface of the first frame body, the lines each traversing the first frame body;
a second frame body made of a dielectric, placed on the upper surface of the first frame body in a way that two end portions of each of the lines are exposed, and including a second opening portion in its center portion;
a seal member placed on an upper surface of the second frame body, and including a third opening portion in its center portion; and
a lid portion placed on an upper surface of the seal member, wherein:
a thickness of the seal member is substantially equal to that of the base substrate, and a coefficient of linear expansion of the seal member is substantially equal to that of the base substrate;
the base substrate, the first frame body, the second frame body, the seal member and the lid portion form a space; and
one of the two end portions of each of the lines is exposed to the space.

2. The semiconductor package according to claim 1, wherein
the base substrate and the seal member are made of the same metal.

3. The semiconductor package according to claim 1, wherein:
the base substrate is made of an alloy of copper and molybdenum; and
the seal member is made of an alloy of iron, nickel and cobalt.

4. A high-frequency semiconductor device comprising:
the semiconductor package according to any one of claims 1 to 3;
a semiconductor chip situated in the space of the semiconductor package, and placed on the surface of the base substrate; and
conductors electrically connecting the semiconductor chip and the end portions of the lines exposed to the space.
